(19) United States
(12) Patent Application Publication
(10) Pub. No.: US 2024/0249091 A1
(43) Pub. Date: Jul. 25, 2024

(54) ELECTRONIC COMPONENT MANAGEMENT METHOD

(71) Applicant: Murata Manufacturing Co., Ltd., Nagaokakyo-shi (JP)

(72) Inventors: Kiyoyuki NAKAGAWA, Nagaokakyo-shi (JP); Koichi IWAMOTO, Nagaokakyo-shi (JP)

(21) Appl. No.: 18/627,478

(22) Filed: Apr. 5, 2024

Related U.S. Application Data
(63) Continuation of application No. PCT/JP2022/034184, filed on Sep. 13, 2022.

(30) Foreign Application Priority Data
Oct. 29, 2021 (JP) 2021-177990

(51) Int. Cl. G06K 7/10; G06K 19/077; G06Q 10/087

(52) U.S. Cl. CPC G06K 7/10366; G06K 19/07758; G06Q 10/087

(57) ABSTRACT

A method includes manufacturer-side steps and user-side steps, the manufacturer-side steps include preparing an electronic component accommodation reel including an RFID tag storing a unique ID and storing electronic components, storing manufacturer-side information in association with the unique ID in a manufacturer-side information storage area of a cloud, shipping the electronic components in the form of the electronic component accommodation reel. The user-side steps include receiving and loading the electronic component accommodation reel shipped from the manufacturer-side facility, reading the unique ID stored in the RFID tag, and acquiring, based on the unique ID read, manufacturer-side information stored in the manufacturer-side information storage area of the cloud.

### CROSS REFERENCE TO RELATED APPLICATIONS

This application claims the benefit of priority to Japanese Patent Application No. 2021-177990 filed on Oct. 29, 2021 and is a Continuation Application of PCT Application No. PCT/JP2022/034184 filed on Sep. 13, 2022. The entire contents of each application are hereby incorporated herein by reference.

### BACKGROUND OF THE INVENTION

### 1. Field of the Invention

The present invention relates to electronic component management methods.

### 2. Description of the Related Art

Conventionally, in a supplier that manufactures small electronic components such as semiconductor chips and capacitor chips, a plurality of manufactured electronic components are accommodated in a single accommodation body, transported and accommodated in a factory, and shipped to an assembly manufacturer in the form of the accommodation body. As for the accommodation body, various configurations have been known in which a tape holding electronic components one by one is wound around a reel, a magazine in which electronic components are aligned and accommodated, a bulk case in which the electronic components are accommodated in a loose state, i.e., in a bulk state, a bagging method, and the like (for example, refer to Japanese Unexamined Patent Application Publication No. 2005-324839). Further, in order to perform manufacturing management of products, a technology has been known which uses an RFID tag system in which an RFID tag is attached to an individual component to be managed and ID information preset in the RFID tag is read (for example, refer to Japanese Unexamined Patent Application Publication No. 2002-358494).

### SUMMARY OF THE INVENTION

As electronic components have been significantly reduced in size, it is considered how to manage an accommodation body in order to manage a large amount of electronic components. However, Japanese Unexamined Patent Application Publication Nos. 2005-324839 and 2002-358494 do not refer to management of the accommodation body in various forms, and there is room for improvement.

Example embodiments of the present invention provide electronic component management methods that are each able to achieve various management forms of an accommodation body in which a plurality of electronic components are accommodated, on the supplier side of the electronic components and on the assembly manufacturer side of the electronic components.

An example embodiment of the present invention provides an electronic component management method that includes manufacturer-side steps performed at a manufacturer-side facility where a manufacturer manufactures electronic components, and user-side steps performed at a user-side facility where a user uses the electronic components manufactured in the manufacturer-side facility, in which the manufacturer-side steps include preparing an electronic component accommodation reel including a reel around which a tape accommodating a plurality of electronic components and an RFID tag storing a unique number is wound, the RFID tag being supplied to at least one of the tape or the reel, storing manufacturer-side information in a manufacturer-side information storage area of an external storage device in association with the unique number, and shipping the electronic component accommodation reel, and the user-side steps include receiving and loading the electronic component accommodation reel shipped from the manufacturer-side facility, reading the unique number stored in the RFID tag, and acquiring, based on the unique number read, manufacturer-side information stored in the manufacturer-side information storage area of the external storage device.

An example embodiment of the present invention provides an electronic component management method that includes manufacturer-side steps performed at a manufacturer-side facility where a manufacturer manufactures electronic components, and user-side steps performed at a user-side facility where a user uses the electronic components manufactured at the manufacturer-side facility, in which the manufacturer-side steps include preparing an electronic component accommodation reel including a reel around which a tape accommodating a plurality of electronic components and an RFID tag supplied to at least one of the tape or the reel is wound, preparing a unique number associated with manufacturer-side information, storing the manufacturer-side information in a manufacturer-side information storage area of an external storage device in association with the unique number, writing the unique number into the RFID tag, and shipping the electronic component accommodation reel, and the user-side steps include receiving and loading the electronic component accommodation reel shipped from the manufacturer-side facility, reading the unique number stored in the RFID tag, and acquiring, based on the unique number read, manufacturer-side information stored in the manufacturer-side information storage area of the external storage device.

According to example embodiments of the present invention, it is possible to provide electronic component management methods that are each able to achieve various management forms of electronic component accommodation reels in each of which a plurality of electronic components are accommodated, on the supplier side of the electronic components and on the assembly manufacturer side of the electronic components.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of electronic components and an electronic component accommodation reel according to an example embodiment of the present invention.

FIG. 2 is a partial plan view of a tape according to an example embodiment of the present invention.

FIG. 3 is a plan view of an RFID tag according to an example embodiment of the present invention.

FIG. 4 is a perspective view of a configuration in which a tape is wound around a reel according to an example embodiment of the present invention.

FIG. 5 is a side view of an electronic component accommodation reel according to an example embodiment of the present invention.

FIG. 6A is a block diagram of a hardware configuration for managing electronic components provided in each of a supplier and an assembly manufacturer according to an example embodiment of the present invention.

FIG. 6B is a schematic diagram of a configuration in the cloud according to an example embodiment of the present invention.

FIG. 7 is a diagram of an image in which a unique ID is written in an RFID tag according to an example embodiment of the present invention.

FIG. 8 is a block diagram of a configuration of a component supply device included in a mounter serving as a mounting device according to an example embodiment of the present invention, and shows an image in which a designated unique ID is written in the component supply device.

FIG. 9 is a flowchart showing an outline of an electronic component management method according to an example embodiment of the present invention.

FIG. 10 is a flowchart showing details of manufacturer steps on a supplier side in an electronic component management method according to an example embodiment of the present invention.

FIG. 11 is a flowchart showing details of user steps on an assembly manufacturer side in an electronic component management method according to an example embodiment of the present invention.

FIG. 12 is a perspective view of an example of a method of reading information of an RFID tag included in an electronic component accommodation reel in a supplier.

FIG. 13 is a perspective view of an example of a method of reading information of an RFID tag included in an electronic component accommodation reel picked from a storage location in a supplier.

FIG. 14 is a side view of an electronic component accommodation reel to which a label is attached on a supplier side.

FIG. 15 is a perspective view of an example of a packaging method of a plurality of electronic component accommodation reels at the time of shipment of the electronic component accommodation reels.

FIG. 16 is a perspective view showing a case where an RFID tag is read during transportation of a plurality of electronic component accommodation reels packaged at the time of shipment.

FIG. 17 is a perspective view of another method of reading an RFID tag at the time of shipment.

FIG. 18 is a side view of an electronic component accommodation reel in which an identification sticker is attached to a label on the assembly manufacturer side.

FIG. 19 is a schematic diagram of a case where a reel operator reads a unique ID in a assembly manufacturer.

FIG. 20 is a diagram of an image in which unique IDs used in each of a supplier and an assembly manufacturer are associated with a common unique ID.

### DETAILED DESCRIPTION OF THE EXAMPLE EMBODIMENTS

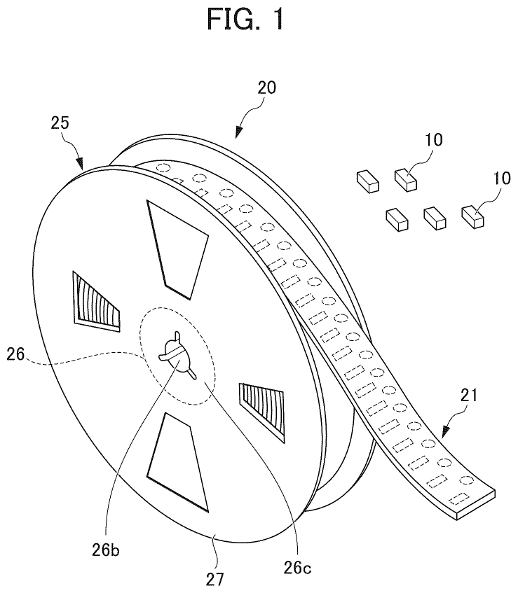

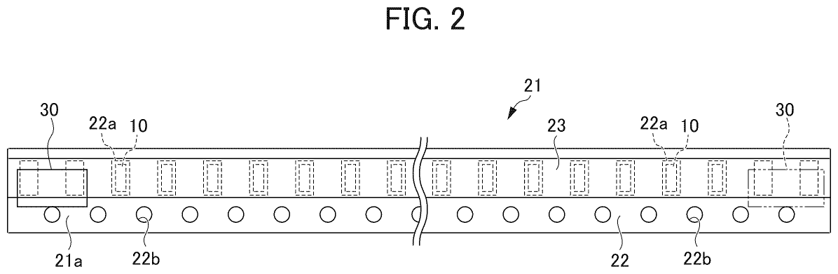

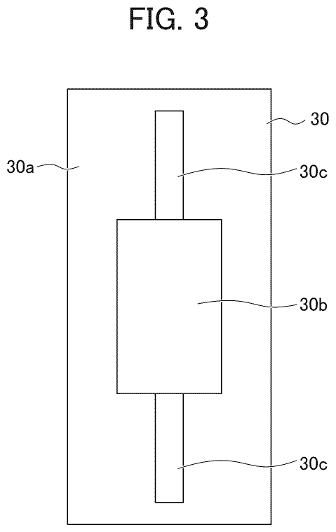

Hereinafter, example embodiments will be described with reference to the drawings. FIG. 1 shows an electronic component accommodation reel 20 according to an example embodiment of the present invention. The electronic component accommodation reel 20 includes a tape 21 in which a plurality of electronic components 10 are accommodated, and a reel 25 around which the tape 21 is wound. FIG. 2 shows the tape 21 in which a plurality of electronic components 10 are accommodated. FIG. 3 shows an example of the configuration of an RFID tag 30 included in the electronic component accommodation reel 20.

As shown in FIG. 2, the tape 21 includes a carrier tape 22 and a cover tape 23 covering the surface of the carrier tape 22. The carrier tape 22 has a long strip shape using a flexible resin, paper, or the like as a material. The carrier tape 22 includes a plurality of accommodation portions 22a and a plurality of feed holes 22b. Each of the accommodation portions 22a is a rectangular or substantially rectangular recess opened toward the front surface side of the carrier tape 22 in a plan view. One electronic component 10 is accommodated in one accommodation portion 22a. Examples of each of the electronic components 10 includes a semiconductor chip or a multilayer ceramic capacitor, and such an electronic component 10 is, for example, a small rectangular or substantially rectangular parallelepiped electronic component having a longitudinal length of about 1.2 mm or less, for example. The plurality of accommodation portions 22a are provided in one line at a predetermined interval in the longitudinal direction of the carrier tape 22. The plurality of accommodation portions 22a are biased toward one side in the width direction of the carrier tape 22.

Each of the plurality of feed holes 22b is a circular or substantially circular through hole penetrating through the front and back surfaces of the carrier tape 22. The plurality of feed holes 22b are provided in a line at a predetermined interval in the longitudinal direction of the carrier tape 22. The plurality of feed holes 22b are biased to the side opposite to the plurality of accommodation portion 22a in the width direction of the carrier tape 22. The teeth of a conveying sprocket (not shown) fit into the plurality of feed holes 22b. The tape 21 is conveyed by the rotation of the conveying sprocket.

The cover tape 23 is made of, for example, a transparent flexible resin, and is a long belt-shaped adhesive tape having an adhesive surface on one side. The cover tape 23 is attached to the carrier tape 22 in a state where the adhesive surface is in close contact with the surface of the carrier tape 22 to cover each of the plurality of accommodation portions 22a and the plurality of feed hole 22b are not blocked. With such a configuration, each of the electronic components 10 is accommodated in a state sealed in a respective one of the plurality of accommodation portions 22a. The tape 21 accommodating the plurality of electronic components 10 is wound around the reel 25 with the surface side of the tape 21 to which the cover tape 23 is attached as the inner peripheral side. The plurality of electronic components 10 are carried together with the reel 25.

As shown in FIG. 2, an RFID tag 30 is attached to one end of the tape 21. The RFID tag 30 may be attached to the other end of the tape 21. The RFID tag 30 may be attached to both one end and the other end of the tape 21. The RFID tag 30 may be attached to the reel 25.

As shown in FIG. 3, the RFID tag 30 is a passive transponder including a rectangular sheet 30a made of resin serving as a base material, an RFID chip 30b including a semiconductor integrated circuit, and a plurality of antennas 30c to communicate with an external device. The RFID chip 30b and the antenna 30c are attached to the sheet 30a. The RFID tag 30 may be of a type in which the RFID chip 30b and the antenna 30c are embedded in the sheet 30a. Alternatively, the RFID tag 30 may be of a type provided with a power source unit. The RFID chip 30b includes a CPU, memory, a communication circuit, and the like.

The RFID tag 30 may be of a type in which memory cannot be rewritten (RO: Read Only), a type in which memory can be rewritten once (WORM: Write Once Read Many), or a type in which memory can be rewritten (R/W: Read and Write). In a case where the type of the RFID tag 30 is RO or WORM, the cost is low although information to be written is smaller than that of R/W.

In the RFID tag 30 of the present example embodiment, when a signal is received from a direction intersecting the surface of the sheet 30a serving as a base material, the reception sensitivity is good and information can be easily read and written. In particular, when a signal is received at an angle orthogonal or substantially orthogonal to the surface of the sheet 30a, the reception sensitivity becomes high, and reading and writing are easier.

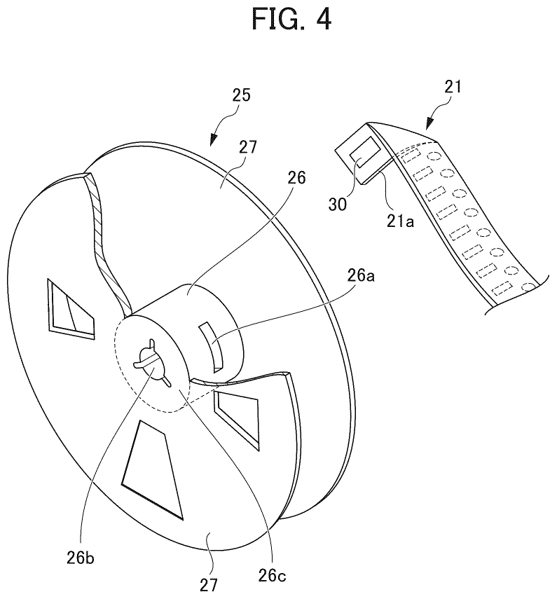

FIG. 4 shows a partially cutaway view of the reel 25. As shown in FIG. 4, the reel 25 includes a winding core 26 and a pair of disk-shaped flanges 27 provided at both axial end portions of the winding core 26. The reel 25 is a resin molded body. The tape 21 in which the electronic components 10 are accommodated is wound around the winding core 26, and the tape 21 is sandwiched between the pair of flanges 27 such that the electronic component accommodation reel 20 shown in FIG. 1 is provided. The electronic component accommodation reel 20 accommodates, for example, several hundreds of electronic components 10. The winding core 26 includes a center having an engagement hole 26b with which a rotation shaft (not shown) rotatably supporting the reel 25 is engaged.

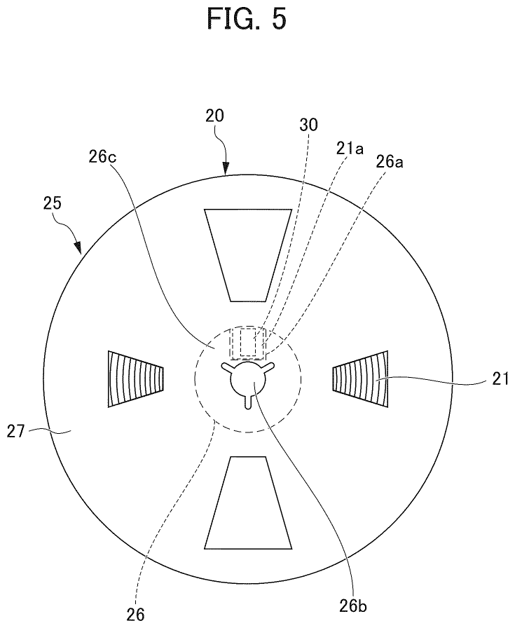

As shown in FIG. 4, the winding core 26 includes a slit 26a extending along the circumferential direction of the winding core 26 of the reel 25. The front end portion 21a of the tape 21 provided with the RFID tag 30 is inserted into the slit 26a, such that the tape 21 is wound around the winding core 26. The front end portion 21a of the tape 21 is inserted into the slit 26a in a state where the surface direction thereof is substantially perpendicular to the axial direction of the winding core 26. A portion of the tape 21 that extends from the slit 26a to the outer peripheral surface of the winding core 26 is folded such that the surface side to which the cover tape 23 is attached overlaps the outer peripheral surface of the winding core 26, such that the tape 21 is wound around the winding core 26. With such a configuration, as shown in FIG. 5, the RFID tag 30 provided at the front end portion 21a of the tape 21 is provided on the winding core 26 in a state facing the side surface 26c of the winding core 26. With such a configuration, only the thin side surface 26c of the winding core 26 exists between the outside and the RFID tag 30, and the read/write signal can be easily received at an angle orthogonal or substantially orthogonal to the surface of the RFID tag 30. Therefore, it is possible to facilitate reading and writing with respect to the RFID tag 30.

Further, when the RFID tag 30 is attached to the other end portion of the tape 21, since the surface of the RFID tag 30 is provided in a state along the outer peripheral surface of the winding core 26, reading and writing from the radial direction of the reel 25 orthogonal to the outer peripheral surface can be facilitated. In addition, when the RFID tag 30 is attached to both one end portion and the other end portion of the tape 21, reading from the side surface and reading from either of the radial directions can be facilitated.

The slit 26a of the winding core 26 may have a general shape extending in the axial direction of the winding core 26. In this case, the tape 21 having the end portion 21a inserted into the slit 26a can be wound on the winding core 26 as it is without being folded as described above.

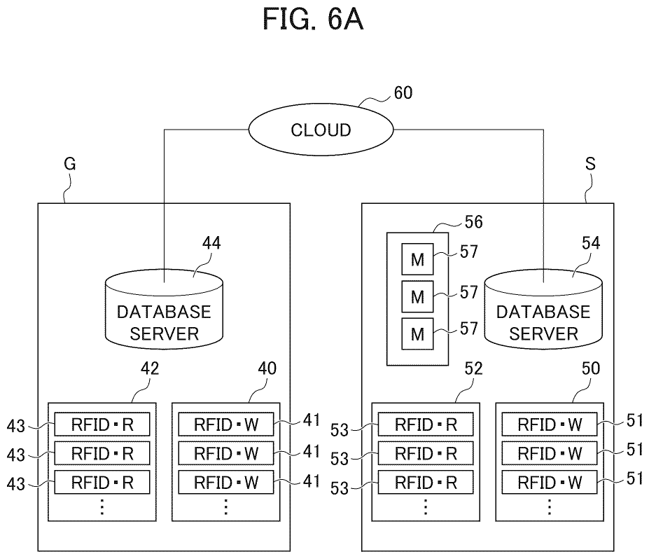

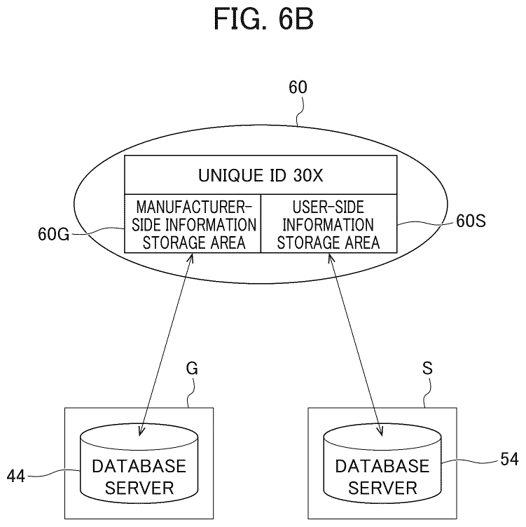

FIG. 6A shows a hardware configuration for managing the electronic components 10 provided in each of the supplier G manufacturing the electronic components 10 and the assembly manufacturers S using the electronic components 10. The supplier G is an example of a manufacturer-side facility that manufactures the electronic components 10. The assembly manufacturer S is an example of a user-side facility using the electronic components 10.

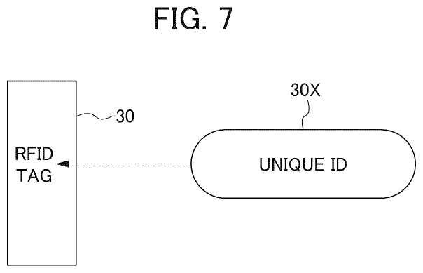

As shown in FIG. 7, a unique ID 30X as a unique number to identify the electronic component accommodation reel 20 is written in the RFID tag 30. The unique ID 30X is written in the RFID chip 30b. In addition, the unique ID 30X includes character strings or numerical strings including a plurality of numerals, symbols, alphabets, etc., and are different for each RFID tag 30. Herein, these unique IDs different for each RFID tag 30 are collectively referred to as the unique ID 30X.

When the RFID tag 30 is RO, the RFID tag 30 in which the unique ID 30X is written in advance and accommodated is attached to the tape 21. When the RFID tag 30 is WORM or R/W, the unique ID 30X is written and accommodated in the RFID tag 30 by the writer unit 40. Writing of the unique ID 30X to the RFID tag 30 may be performed before the RFID tag 30 is attached to the tape 21, or may be performed after the RFID tag 30 is attached to the tape 21. Alternatively, writing of the unique ID 30X to the RFID tag 30 may be performed after the RFID tag 30 is attached to the tape 21 and the tape 21 is wound around the reel 25.

As shown in FIG. 6A, the supplier G includes a writer unit 40 capable of writing a unique ID 30X associated with manufacturer side information, which is information on the supplier G side, into the RFID tag 30 provided in the electronic component accommodation reel 20 by being attached to the tape 21, a reader unit 42 to read the unique ID 30X associated with the manufacturer side information recorded in the RFID tag 30 provided in the electronic component accommodation reel 20, and a database server 44. The writer unit 40 and the reader unit 42 may be integrated with each other. The database server 44 is prepared on the supplier G side.

The writer unit 40 writes the unique ID 30X and the manufacturer side information into the RFID tag 30. In the database server 44, the unique ID 30X and the manufacturer side information are mutually associated or linked and accommodated. The reader unit 42 reads the unique ID 30X written in the RFID tag 30. When the supplier G uses the reader unit 42 to read the unique ID 30X, the supplier G accesses the database server 44, and can read the manufacturer side information stored in the database server 44 in association with the unique ID 30X.

The database server 44 on the supplier G side can be connected to a cloud 60 on the Internet together with a database server 54 on the assembly manufacturer S side described later. The cloud is an abbreviation for cloud computing. Cloud computing is a generic term for services that enable use of various resources such as software, hardware, database, and storage area(s) via a communication line such as the Internet. In the present example embodiment, the cloud 60 is an example of an external storage device, and more specifically, a storage area in cloud computing is an example of an external storage device.

The external storage device may not necessarily be a storage area in cloud computing, and may be any storage device which can be accessed by the supplier G and the assembly manufacturer S via a communication line. The database server 44 and the database server 54 may be provided on the cloud 60.

As shown in FIG. 6B, the cloud 60 includes a manufacturer-side information storage area 60G to store the manufacturer-side information, and a user-side information storage area 60S to store the user-side information on the assembly manufacturer S side described later. A portion or all of the unique ID 30X and the manufacturer side information stored in the database server 44 on the supplier G side are copied and stored in the cloud 60. A portion or all of the unique ID 30X and the user-side information stored in the database server 54 of the assembly manufacturer S are copied and stored in the cloud 60. By accessing the cloud 60, both the supplier G and the assembly manufacturer S can share both pieces of information associated with the unique ID 30X.

The writer unit 40 includes a plurality of RFID writers 41 capable of writing information in a non-contact manner. Each of the plurality of RFID writers 41 is provided at a predetermined position in the factory of the supplier G. Each of the RFID writers 41 copies and stores a portion or all of the unique ID 30X and the manufacturer side information read from the database server 44, in the manufacturer side information storage area 60G of the cloud 60. The reader unit 42 includes a plurality of RFID readers 43 capable of reading the unique ID 30X associated with the manufacturer side information in a non-contact manner. Each of the plurality of RFID readers 43 is provided at a predetermined position in the factory of the supplier G. The read information of the RFID reader 43 is stored in the database server 44 and the manufacturer-side information storage area 60G of the cloud 60.

The assembly manufacturer S includes a writer unit 50 capable of writing a unique ID 30X associated with user-side information, which is information on the assembly manufacturer S side, to the RFID tag 30 of the electronic component accommodation reel 20, a reader unit 52 to read the unique ID 30X recorded in the RFID tag 30 of the electronic component accommodation reel 20, a database server 54, and a mounter 56. The mounter 56 is an example of a mounting device. When the type of the RFID tag 30 is WORM or R/W, the writer unit 50 may be omitted.

The writer unit 50 writes the unique ID 30X and the user side information into the database server 54. In the database server 54, the unique ID 30X and the user side information are mutually associated and stored. The reader unit 52 reads the unique ID 30X written in the RFID tag 30. When the reader unit 52 reads the unique ID 30X, the reader unit 52 accesses the database server 54 to read the user-side information stored in the database server 54 in association with the unique ID 30X.

The writer unit 50 includes a plurality of RFID writers 51 capable of writing information in a non-contact manner. Each of the plurality of RFID writers 51 is provided at a predetermined position in the factory of the assembly manufacturer S. Each of the RFID writers 51 may write and record the unique ID 30X associated with the user-side information and the manufacturer-side information in the RFID tag 30. The reader unit 52 includes a plurality of RFID readers 53 capable of reading the unique ID 30X in a non-contact manner. The reader unit 52 is an example of a first reader. Each of the plurality of RFID readers 53 is provided at a predetermined position in the factory of the assembly manufacturer S. The read information of the RFID reader 53 is stored in the database server 54 and the user-side information storage area 60S of the cloud 60.

At the supplier G, the reader unit 42 can read a portion (for example, the number of electronic components 10 to be used) or all of the user information associated with the unique ID 30X and stored in the user-side information storage area 60S of the cloud 60. Further, in the assembly manufacturer S, the reader unit 52 can read a portion (for example, the number of electronic components 10 to be produced or the like) or all of the manufacturer information stored in the manufacturer-side information storage area 60G of the cloud 60 in association with the unique ID 30X.

The mounter 56 is a device operative to mount at least one electronic component 10 on an electronic circuit board included in an electronic device set. The mounter 56 includes a plurality of component supply devices 57. In each component supply device 57, the electronic component accommodation reel 20 is set, and the tape 21 is unwound to supply the electronic components 10 to the mounter 56.

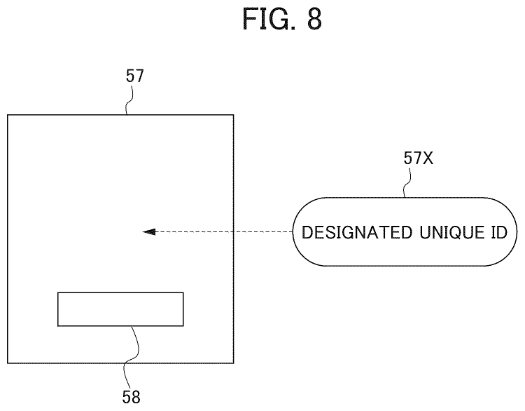

As shown in FIG. 8, a designated unique ID 57X is electronically written and stored in each component supply device 57 of the mounter 56. Each component supply device 57 of the mounter 56 includes an RFID reader 58 that reads the RFID tag 30 of the electronic component accommodation reel 20. The designated unique ID 57X is an example of a designated unique number. The RFID reader 58 is an example of a second reader.

The supplier G conveys and stores the plurality of electronic components 10 manufactured in the factory in the state of the electronic component accommodation reel 20, and ships the plurality of electronic components 10 to the assembly manufacturer S. The assembly manufacturer S receives the plurality of electronic component accommodation reels 20, and mounts the plurality of electronic components 10 within the electronic component accommodation reels 20 on electronic circuit boards, each included in the electronic device set by using the mounter 56. The assembly manufacturer S manufactures electronic circuit boards or the like.

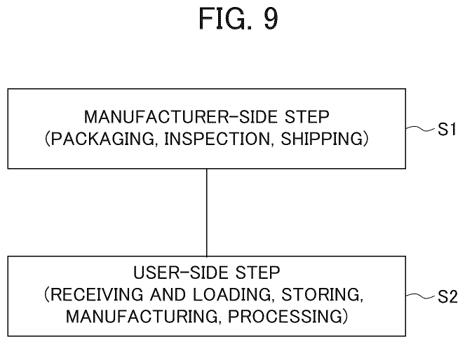

As shown in FIG. 9, in the supplier G, the manufacturer-side step S1 is performed. The manufacturer-side step S1 in the supplier G includes a packaging process, an inspection process, and a shipping process of the electronic components 10. Further, in the assembly manufacturer S, the user-side step S2 is performed. The user-side step S2 in the assembly manufacturer S includes a receiving process, a storage process, a manufacturing process, and a processing process of the electronic components 10. At the supplier G, the plurality of manufactured electronic components 10 are accommodated in the tape 21, and the tape 21 is wound around the reel 25 to provide an electronic component accommodation reel 20. A plurality of electronic component accommodation reels 20 are shipped from the supplier G. The plurality of electronic component accommodation reels 20 shipped from the supplier G are received and used by the assembly manufacturer S.

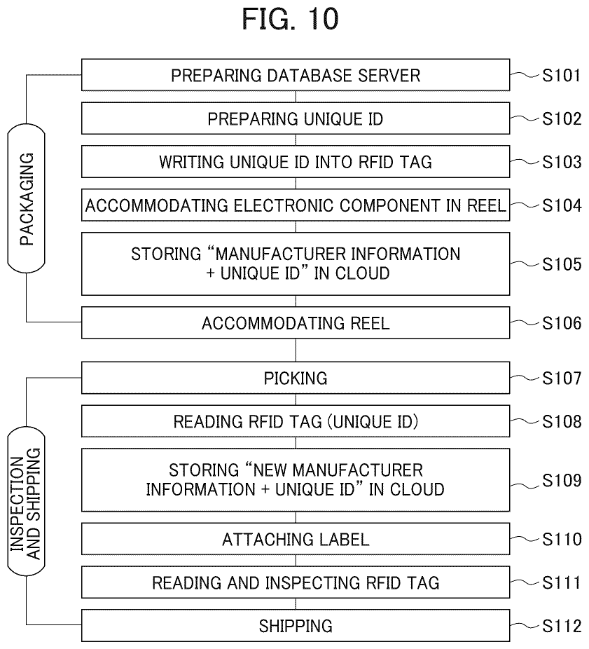

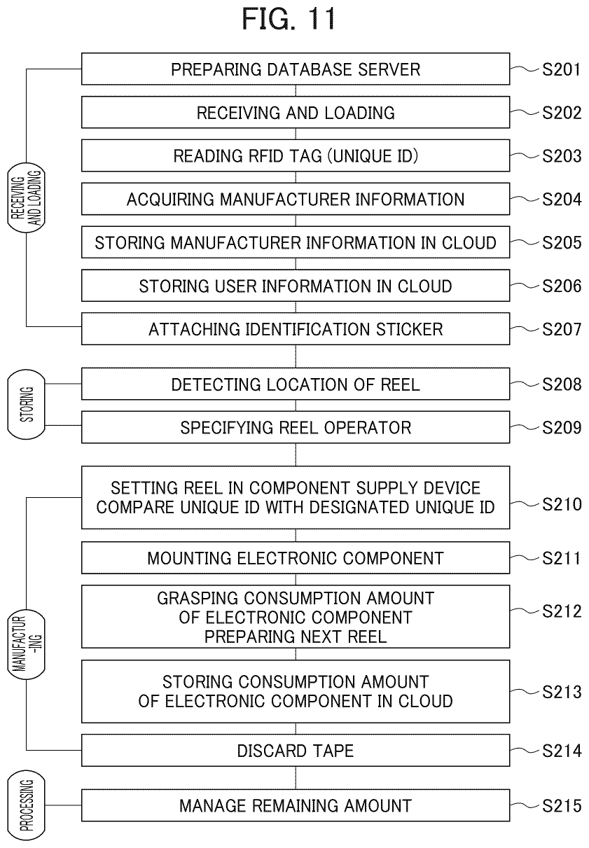

The flow of the electronic components 10 in the supplier G and the assembly manufacturer S will now be described with reference to FIGS. 10 and 11. The “reel” shown in FIGS. 10 and 11 refers to the electronic component accommodation reel 20.

### Manufacturer-Side Steps at Supplier G

FIG. 10 shows the details of the manufacturer-side step S1 which is the flow of the electronic components 10 on the supplier G side.

At the supplier G, the database server 44 storing manufacturer-side information described later is prepared in advance (step S101). Further, at the supplier G, the unique ID 30X to identify the electronic component accommodation reel 20 is prepared for each electronic component accommodation reel 20 (step S102).

### Packaging Process

In the packaging process, when the RFID tag 30 is WORM or R/W, the prepared unique ID 30X is written to the RFID tag 30 before or after the RFID tag 30 is attached to the electronic component accommodation reel 20 (step S103). Next, the plurality of manufactured electronic components 10 are accommodated in the tape 21, and the tape 21 is wound around the reel 25 to be accommodated in the electronic component accommodation reel 20 (step S104). As a result, the electronic component accommodation reel 20 is prepared which accommodates the plurality of electronic components 10 and including the RFID tag 30 storing the unique ID 30X.

When the RFID tag 30 included in the electronic component accommodation reel 20 is RO, the unique ID 30X is stored in advance in the RFID tag 30. In this case, step S103 is omitted, and the plurality of electronic components 10 are accommodated in the tape 21.

In the packaging process, the manufacturer side information is stored in the database server 44 in association with the unique ID 30X held by the RFID tag 30 of the electronic component accommodation reel 20, and is stored in the manufacturer side information storage area 60G of the cloud 60 (step S105). The manufacturer side information is a plurality of pieces of information which are related to the electronic components 10 accommodated in the tape 21 and are set or held by the supplier G side. Examples of the manufacturer-side information include a lot number of the electronic component 10, the quantity of the electronic components 10 accommodated in the electronic component accommodation reel 20, product information such as performance of the electronic component 10, environmental information of the electronic component 10, an inspection number of the electronic component 10, and the like. Depending on the kind of the electronic component 10, MSL (Moisture Sensitivity Level) is recorded. The MSL refers to a level indicating a risk for a phenomenon whereby volume expansion due to vaporization of moisture contained in the electronic component 10 occurs to cause a failure. It is also possible to obtain information on the manufacturing process of the electronic component 10 via the lot number. In this case, the unique ID 30X is used as a key, or information is acquired by using a key stored in the RFID tag 30 together with the unique ID 30X.

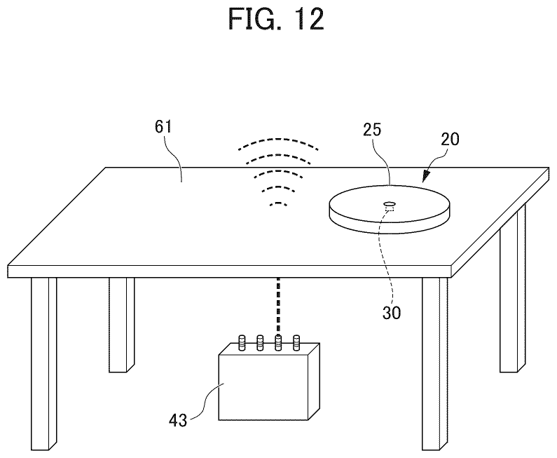

In the factory of the supplier G, the RFID tag 30 of the electronic component accommodation reel 20 is read by a predetermined RFID reader 43, and the manufacturer side information associated with the unique ID 30X is read, such that the electronic component accommodation reel 20 is managed. In order to read the unique ID 30X of the RFID tag 30, for example, as shown in FIG. 12, the unique ID 30X of the RFID tag 30 of the electronic component accommodation reel 20 placed on the table 61 is read by the RFID reader 43 placed around the table 61.

The plurality of electronic component accommodation reels 20 from which the unique ID 30X of the RFID tag 30 is read are carried in the factory and stored in a predetermined storage location (step S106). Then, until the next inspection/processing process, based on the unique ID 30X stored in the RFID tag 30, for example, inventory information management in the factory, location management based on a travel route, security management, and the like are performed. The inventory information management, the location management, and the security management are performed based on the reading information of the RFID reader 43 provided in the factory. The RFID reader 43 is provided, for example, in a gate provided in a passage, an entrance/exit port into a room, or the like, and reads the unique ID 30X recorded in the RFID tag 30 when the electronic component accommodation reel 20 passes through the RFID reader 43.

The inventory information management is performed to manage inventory by checking whether or not the electronic component accommodation reel 20 is accommodated in a predetermined storage location. For example, when the electronic component accommodation reel 20 passes through a gate provided at an entrance/exit port to a predetermined storage location, the unique ID 30X of the RFID tag 30 is read by the RFID reader 43 provided at the gate, thereby confirming the inventory as in stock.

The location management is management in which the electronic component accommodation reel 20 carried in the factory passes through a plurality of gates or moves into or out of a predetermined room, thereby determining the location of the electronic component accommodation reel 20 in the factory in detail. Since the RFID tag 30 cannot be detected by the RFID reader 43 or the like when the RFID tag 30 is accommodated in a metal case, the position of the RFID tag 30 can be determined more accurately by using a metal detector or an X-ray inspection apparatus in combination.

The security management is, for example, management to determine that one electronic component accommodation reel 20 is not shipped on a regular route when the electronic component accommodation reel 20 is out of the factory in a state in which shipping is not confirmed by the RFID tag 30, and a warning is issued.

### Inspection/Shipment Process

In the inspection/shipment process, the electronic component accommodation reel 20 is picked from the storage location (step S107), and then the unique ID 30X stored in the RFID tag 30 included in the picked electronic component accommodation reel 20 is read (step S108).

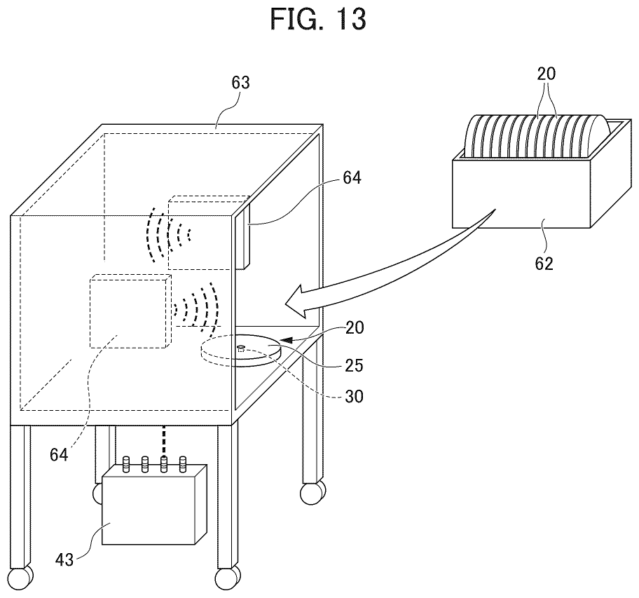

For example, as shown in FIG. 13, the electronic component accommodation reel 20 is picked from a storage location 62 such as a rack and placed on a cart 63 for transportation, and on the cart 63, the unique ID 30X of the RFID tag 30 is read by the RFID reader 43 via a sensor 64. The RFID reader 43 is installed at an appropriate position of the cart 63. Thus, information indicating that the electronic component accommodation reel 20 is shipped is inputted to the database server 44. When the electronic component accommodation reel 20 is apart from the readable distance of the RFID reader 43, the unique ID 30X recorded in the RFID tag 30 may be read through the sensor 64 in the vicinity of the electronic component accommodation reel 20.

Here, in the manufacturer-side information storage area 60G of the cloud 60, new manufacturer-side information is further stored via the database server 44 in association with the unique ID 30X of the RFID tag 30 of the picked electronic component accommodation reel 20 (step S109). Examples of the new manufacturer side information here include, but are not limited to, a part number used by the assembly manufacturer S, an order number from the assembly manufacturer S, a factory number of the supplier G, a date related to manufacturing, and a vendor number.

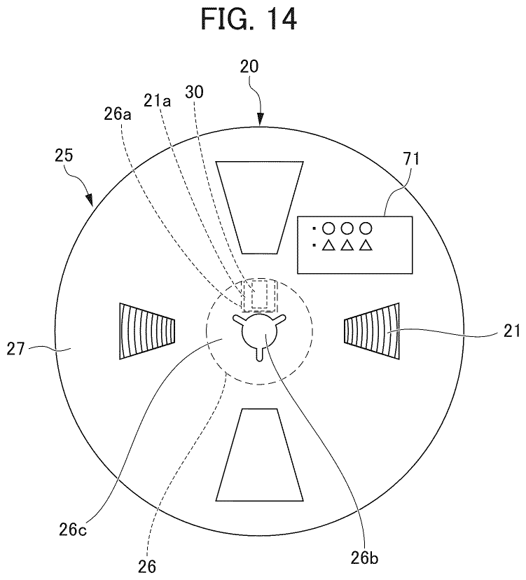

In the present example embodiment, as shown in FIG. 14, a label 71 is attached to the reel 25 of the electronic component accommodation reel 20 (step S110). The label 71 is attached to the surface of one of the flanges 27. On the label 71, at least one piece of manufacturer side information among the manufacturer-side information stored in the database server 44 and the manufacturer-side information storage area 60G of the cloud 60 in association with the unique ID 30X, or another piece of manufacturer-side information necessary for shipping is printed in advance. The manufacturer side information printed on the label 71 can be visually confirmed. The label 71 may include at least one of a one-dimensional barcode and a two-dimensional barcode associated with the manufacturer side information.

The unique ID 30X of the RFID tag 30 of each of the electronic component accommodation reels 20 is read by the RFID reader 43, such that the electronic component accommodation reels 20 are inspected (step S111).

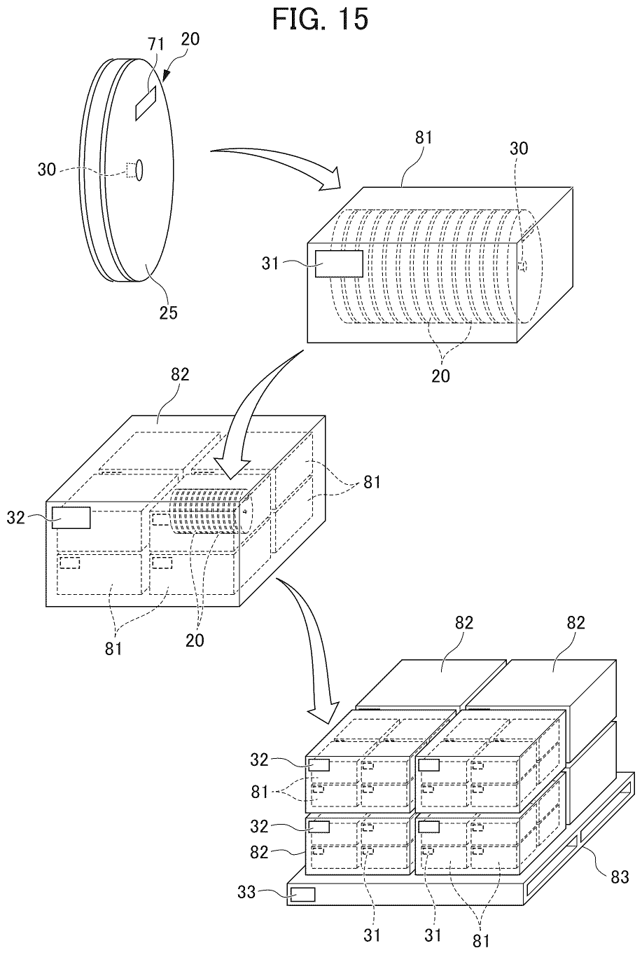

The plurality of electronic component accommodation reels 20 that have been inspected are packaged in a box and shipped to the assembly manufacturer S (step S112). For example, as shown in FIG. 15, a predetermined number of electronic component accommodation reels 20 are accommodated in an exterior box 81, a plurality of exterior boxes 81 stacked in two stages are accommodated in a transport outer box 82, and a plurality of transport outer boxes 82 are loaded on a pallet 83.

The exterior box 81 may include the RFID tag 31 in which the unique ID 30X of the RFID tag 30 of each of the plurality of electronic component accommodation reels 20 accommodated in the exterior box 81 is recorded. Further, the transport outer box 82 may include the RFID tags 32 in which the RFID tag 31 of each of the plurality of exterior boxes 81 accommodated in the transportation outer box 82 is recorded. Further, the pallet 83 may include the RFID tag 33 in which the RFID tag 32 of each of the plurality of transport outer boxes 82 stacked on the pallet 83 is recorded. In this case, the unique ID 30X of the accommodated electronic component accommodation reel 20, the RFID tag 31, the RFID tag 32, and the RFID tag 33 are associated with one another and stored in the database server 44 and the manufacturer-side information storage area 60G of the cloud 60. With such a configuration, the unique IDs 30X of the plurality of electronic component accommodation reels 20 can be collectively read for each of the exterior boxes 81, each of the transport outer boxes 82, and each of the pallets 83.

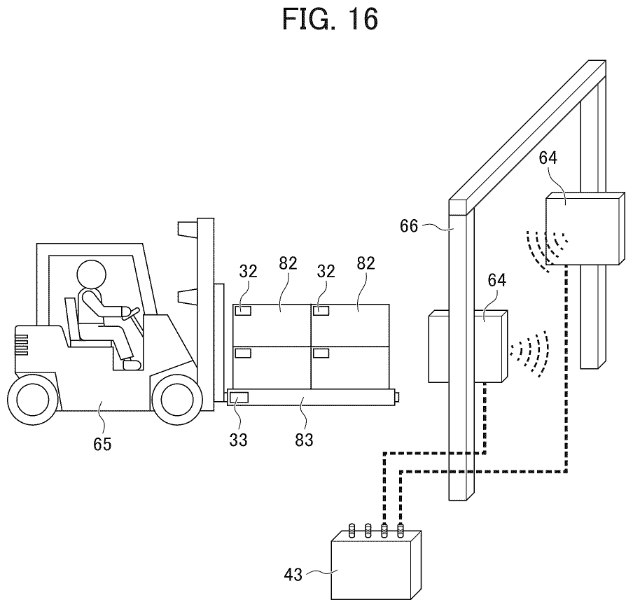

When a plurality of transport outer boxes 82 are stacked on the pallet 83 as described above, the pallet 83 is conveyed to a shipping place by a forklift 65 as shown in FIG. 16. When the forklift 65 passes through the gate 66, the RFID reader 43 reads the RFID tag 31, the RFID tag 32, and the RFID tag 33 via the sensor 64 provided in the gate 66, thereby making it possible to perform shipping management that confirms that the plurality of electronic component accommodation reels 20 associated with the RFID tag 31, the RFID tag 32, and the RFID tag 33 have been shipped.

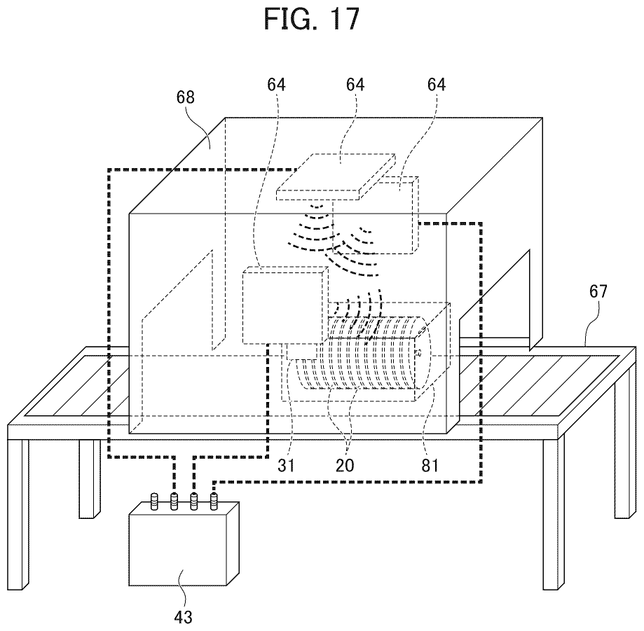

FIG. 17 shows another configuration of reading the RFID tag 30 at the time of shipment. In FIG. 17, the unique ID 30X of the RFID tag 30 is read by the RFID reader 43 via the sensor 64 provided in a tunnel-shaped gate 68 while the exterior box 81 accommodating the plurality of electronic component accommodation reels 20 that are being conveyed by the conveying table 67 is conveyed through the gate 68. The RFID reader 43 accessing the database server 44 reads the manufacturer information associated with the read unique ID 30X.

### User-Side Steps in Assembly Manufacturer S

FIG. 11 shows the details of the user-side step S2, which is the flow of the electronic components 10 on the assembly manufacturer S side. In the assembly manufacturer S, a database server 54 storing user-side information described later is prepared in advance (step S201).

### Receiving Process

In the receiving process, first, the plurality of electronic component accommodation reels 20 are received and loaded to the factory of the assembly manufacturer S (step S202). In the receiving process, the RFID tag 30 of the received electronic component accommodation reel 20 is read by the predetermined RFID reader 53, and the unique ID 30X stored in the RFID tag 30 is read (step S203). Thus, the assembly manufacturer S acquires the manufacturer side information via the cloud 60 based on the read unique ID 30X (step S204). The manufacturer-side information to be acquired includes the lot number of the electronic component 10, the quantity of the electronic components 10 accommodated in the electronic component accommodation reel 20, product information such as performance of the electronic component 10, environmental information about the electronic component 10, an inspection number of the electronic component 10, and the like.

As shown in FIG. 15, when the plurality of electronic component accommodation reels 20 are accommodated in the exterior box 81 or the plurality of exterior boxes 81 are accommodated in the transport outer box 82 and the electronic components 10 are received by and loaded to the assembly manufacturer S, the RFID tag 31 included in the exterior box 81 and the RFID tag 32 included in the transport outer box 82 are read by the RFID reader 53. Thus, the unique IDs 30X of the plurality of electronic component accommodation reels 20 can be collectively read for each of the exterior boxes 81 and each of the transport outer boxes 82.

The assembly manufacturer S stores the manufacturer side information obtained based on the unique ID 30X read from the RFID tag 30 of the received electronic component accommodation reel 20 in the user side information storage area 60S of the cloud 60 (step S205). In some cases, the assembly manufacturer S stores predetermined user side information required by the assembly manufacturer S in the user side information storage area 60S of the cloud 60 as additional information (step S206).

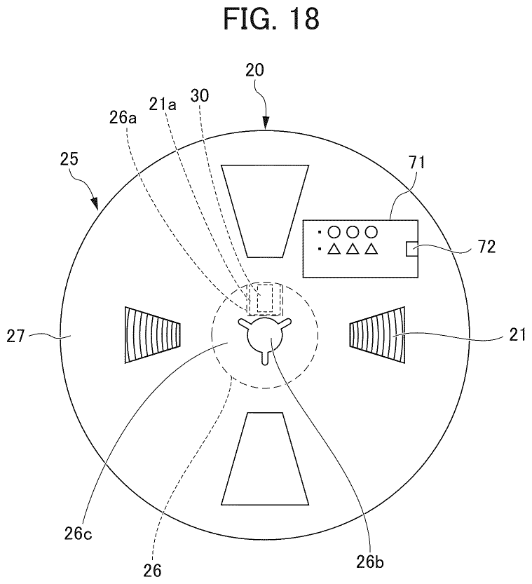

In the present example embodiment, as shown in FIG. 18, a unique identification sticker 72 on the assembly manufacturer S side is attached to the electronic component accommodation reel 20 (step S207). For example, the identification sticker 72 is a sticker having one single color such as red, blue, or yellow, for example, and may be attached to the label 71. The electronic component accommodation reels 20 are sorted in the assembly manufacturer S based on the color of the identification sticker 72. For example, a manufacturing line, a manufacturing order, and the like are selected based on the color of the identification sticker 72.

### Storage Process

When the assembly manufacturer S stores the electronic component accommodation reel 20 in a predetermined storage location or picks the electronic component accommodation reel 20 from the storage location and conveys the electronic component accommodation reel 20 prior to the manufacturing process, the assembly manufacturer S also reads the unique ID 30X of the RFID tag 30 by a predetermined RFID reader 53 to perform the location management of the electronic component accommodation reel 20, i.e., management for detecting a location (step S208). In addition, as in the case of the supplier G, the inventory information management of the electronic component accommodation reel 20, the security management, and the like can be performed by reading the RFID tag 30. Since the RFID tag 30 cannot be detected by the RFID reader 53 or the like when the RFID tag 30 is accommodated in the metal case, a metal detector and an X-ray inspection apparatus are used in combination.

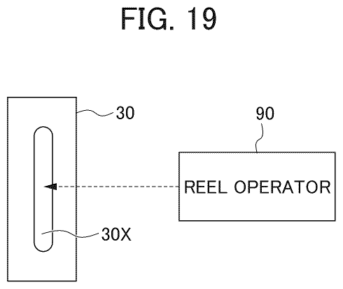

Further, at the assembly manufacturer S, as shown in FIG. 19, the reel operator 90 handling the electronic component accommodation reels 20 reads the unique ID 30X of the RFID tag 30, and this allows the reel operator 90 to be specified as the operator of the electronic component accommodation reels 20 from the read unique ID 30X (step S209). Examples of the reel operator 90 include a work personnel, a work robot, and a transport device such as an unmanned transport vehicle that transports the electronic component accommodation reels 20. When the reel operator 90 is a work personnel, the RFID tag 30 is read by a portable RFID reader. When the reel operator 90 is a work robot or an unmanned transport vehicle, the RFID tag 30 is read by an RFID reader mounted on the work robot or the unmanned transport vehicle.

### Manufacturing Process

In an example of the manufacturing process, the electronic component accommodation reel 20 is dispensed from the storage location toward the mounter 56, and the electronic component accommodation reel 20 is set in each of the plurality of component supply devices 57 included in the mounter 56. In each component supply device 57, the unique ID 30X of the RFID tag 30 of the electronic component accommodation reel 20 is read by the RFID reader 58, and the read unique ID 30X is compared with the designated unique ID 57X designated by the component supply device 57 itself (step S210).

As a result, it is confirmed whether or not the electronic component accommodation reel 20 is the electronic component accommodation reel 20 in which the electronic components 10 to be mounted are accommodated by the component supply device 57, and the replacement of the electronic component 10 is prevented in advance. For example, when the electronic component accommodation reel 20 that stores the electronic components 10 that are not compatible with the component supply device 57 is set, the component supply device 57 does not operate, the electronic component accommodation reel 20 is detached from the component supply device 57, and the next electronic component accommodation reel 20 is set.

The tape 21 is unwound from the electronic component accommodation reel 20 set in the component supply device 57, and the electronic components 10 are supplied from the tape 21 to the mounter 56 one by one to mount the electronic components 10 on the electronic circuit board (step S211).

In each component supply device 57, based on the quantity information of the electronic components 10 accommodated in the electronic component accommodation reel 20 among pieces of the manufacturer side information obtained in step S204, the consumption amount of the electronic components 10 provided in the electronic circuit board and the remaining amount of the electronic components 10 in the electronic component accommodation reel 20 based on the consumption amount are determined. When the remaining amount of the electronic components 10 is lower than a predetermined amount, another electronic component accommodation reel 20 that has been received and loaded is prepared (step S212).

Further, the consumption amount of the electronic components 10 is associated with the unique ID 30X and stored in the database server 54, and further stored in the manufacturer-side information storage area 60G of the cloud 60 (step S213). The supplier G can quickly confirm the consumption amount of the electronic components 10 at the assembly manufacturer S by reading the unique ID 30X. The consumption amount of the electronic components 10 at the assembly manufacturer S at this time may be transmitted to the supplier G by an electronic transmission means such as the Internet or a LAN, or a physical transmitter such as storing the information in a recording medium such as a memory device or a CD-ROM to physically deliver it to the supplier G.

The consumption amount of the electronic components 10 is transmitted from the assembly manufacturer S to the supplier G as described above. At the supplier G, the remaining amount of the electronic components 10 at the assembly manufacturer S is predicted based on the consumption amount of the electronic components 10 transmitted from the assembly manufacturer S. When the remaining amount of the electronic components 10 is lower than a preset remaining amount, the supplier G starts an operation of preparing the electronic component accommodation reel 20 and prepares for shipment.

When all the electronic components 10 in the electronic component accommodation reel 20 are mounted at the assembly manufacturer S, the tape 21 from which the electronic components 10 are taken out is discarded (step S214). The empty reel 25 is returned to the supplier G for reuse. When the RFID tag 30 is attached to the tape 21 and is not attached to the reel 25, the reel 25 can be easily reused.

In the processing process after the manufacturing process, for example, the electronic component accommodation reel 20 in which the electronic components 10 remain is accommodated in a predetermined place as a middle inventory. In this case, the RFID tag 30 of the electronic component accommodation reel 20 is read by the RFID reader 53, and the remaining amount is managed as the electronic component accommodation reel 20 in the middle inventory (step S215).

In addition, in the processing process, by reading the RFID tag 30 of the electronic component accommodation reel 20, it is possible to perform manufacturing tendency management based on the kind of the electronic components 10 to be used or the amount of the electronic device set to be manufactured, security management of the electronic component accommodation reel 20, and the like.

The user side information in step S206 may be stored in the cloud 60. The user-side information stored in the cloud 60 may be accessible from the supplier G side. By making the accessible from the side of the supplier G, the supplier G can know the specification mode and inventory information of the assembly manufacturer S, so that the request of the assembly manufacturer S can be predicted in advance, and the request of the assembly manufacturer S can be flexibly dealt with.

Data stored on the cloud 60 may be stored using a block chain. The use of the block chain makes it difficult to tamper with the data stored on the cloud 60, thereby increasing the reliability of the data stored on the cloud 60.

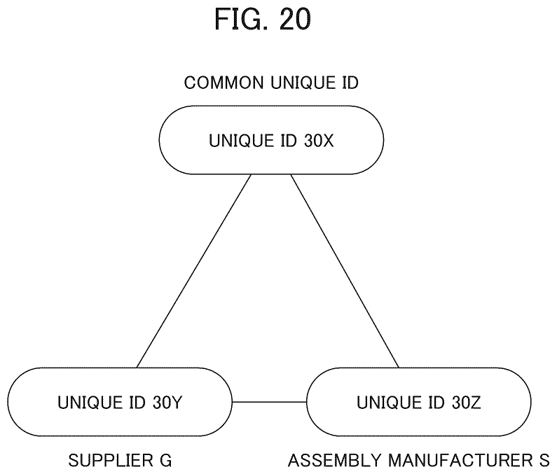

In the above example embodiments, the unique ID 30X written in the RFID tag 30 is common (common unique ID) between the supplier G and the assembly manufacturer S, and therefore, one unique ID 30X is used consistently from the supplier G to the assembly manufacturer S. However, as shown in FIG. 20, a unique ID 30Y that is unique for the supplier may be used on the supplier G side, and a unique ID 30Z that is unique for the assembly manufacturer S may be used on the assembly manufacturer S side. In this case, the unique ID 30Y on the supplier G side and the unique ID 30Z on the assembly manufacturer S side are associated with the common unique ID 30X so that various kinds of information written in the RFID tag 30 can be shared.

Further, one of the unique ID 30Y on the supplier G side or the unique ID 30Z on the assembly manufacturer S side may be the same as the unique ID 30X, and one of the unique ID 30Y on the supplier G side or the unique ID 30Z on the assembly manufacturer S side may be associated with the unique ID 30X.

According to the example embodiments described above, the following advantageous effects are achieved.

An electronic component management method according to the present example embodiment includes manufacturer-side steps performed at the supplier G serving as a manufacturer-side facility where a manufacturer manufactures the electronic components 10, and user-side steps performed at the assembly manufacturer S serving as a user-side facility where a user uses the electronic components 10 manufactured in the supplier G, the manufacturer-side steps including preparing an electronic component accommodation reel 20 including the reel 25 around which the tape 21 accommodating the plurality of electronic components 10 and the RFID tag 30 storing the unique ID 30X serving as a unique number is wound, the RFID tag 30 being supplied to at least one of the tape 21 or the reel 25, storing manufacturer-side information in the manufacturer-side information storage area 60G of the cloud 60 in association with the unique ID 30X, and shipping the electronic component accommodation reel 20, and the user-side steps including receiving and loading the electronic component accommodation reel 20 shipped from the manufacturer-side facility, reading the unique ID 30X stored in the RFID tag 30, and acquiring, based on the unique ID 30X read, manufacturer-side information stored in the manufacturer-side information storage area 60G of the cloud 60.

With such a configuration, it is possible to achieve various management forms of the electronic component accommodation reel 20 in which the plurality of electronic components 10 are accommodated on both the supplier G side and the assembly manufacturer S side by using the unique ID 30X of the RFID tag 30 included in the electronic component accommodation reel 20. Further, it is possible to consistently manage the electronic components 10 from the supplier G to the assembly manufacturer S by using the unique ID 30X written in the RFID tag 30.

An electronic component management method according to the present example embodiment includes manufacturer-side steps performed at the supplier G serving as a manufacturer-side facility where a manufacturer manufactures electronic components 10, and user-side steps performed at the assembly manufacturer S serving as a user-side facility where a user uses the electronic components 10 manufactured in the supplier G, the manufacturer-side steps including preparing the electronic component accommodation reel 20 including the reel 25 around which the tape 21 accommodating the plurality of electronic components 10 and the RFID tag 30 supplied to at least one of the tape 21 or the reel 25 is wound, preparing the unique ID 30X serving as a unique number associated with manufacturer-side information, storing the manufacturer-side information in the manufacturer-side information storage area 60G of the cloud 60 in association with the unique ID 30X, writing the unique ID 30X into the RFID tag 30, and shipping the electronic component accommodation reel 20, and the user-side steps including receiving and loading the electronic component accommodation reel 20 shipped from the manufacturer-side facility, reading the unique ID 30X stored in the RFID tag 30, and acquiring, based on the unique ID 30X read, manufacturer-side information stored in the manufacturer-side information storage area 60G of the cloud 60.

With such a configuration, it is possible to achieve various management forms of the electronic component accommodation reel 20 in which the plurality of electronic components 10 are accommodated on both the supplier G side and the assembly manufacturer S side by using the unique ID 30X of the RFID tag 30 included in the electronic component accommodation reel 20. Further, it is possible to consistently manage the electronic components 10 from the supplier G to the assembly manufacturer S by using the RFID tag 30.

In an electronic component management method according to the present example embodiment, the manufacturer-side steps further include reading the manufacturer-side information based on the unique ID 30X, creating the label 71 based on the manufacturer-side information read, and attaching the label 71 to the electronic component accommodation reel 20.

With such a configuration, it is possible to visually confirm the manufacturer side information by looking at the label 71, and it is also possible to promptly advance management based on the manufacturer side information without requiring a reading device such as an RFID reader.

In an electronic component management method according to the present example embodiment, the manufacturer-side steps further include collectively reading the unique ID 30X from the RFID tag 30 of each of the plurality of the electronic component accommodation reels 20 in a case of shipping the plurality of electronic component accommodation reels 20, each accommodating the plurality of electronic components 10.

With such a configuration, at the supplier G, it is possible to omit the labor of reading the RFID tags 30 of the electronic component accommodation reels 20 one by one, and it is possible to improve the efficiency of management.

In an electronic component management method according to the present example embodiment, the user-side steps further include collectively reading the unique ID 30X from the RFID tag 30 of each of a plurality of the electronic component accommodation reels 20 in a case of receiving and loading the plurality of electronic component accommodation reels 20 shipped.

With such a configuration, in the assembly manufacturer S, it is possible to omit the labor of reading the RFID tags 30 of the electronic component accommodation reels 20 one by one, and it is possible to improve the efficiency of management.

In an electronic component management method according to the present example embodiment, the user-side steps further include reading the RFID tag 30 by the RFID reader 53 serving as a first reader installed at a predetermined location of the assembly manufacturer S to detect a location of the electronic component accommodation reel 20.

With such a configuration, it is possible to constantly know the location of the electronic component accommodation reel 20, and it is possible to perform various management processes such as inventory information management, location management, and security management.

In an electronic component management method according to the present example embodiment, the user-side steps further include the reel operator 90 allocated at a predetermined location in the assembly manufacturer S reading the RFID tag 30 to specify the reel operator 90.

With such a configuration, it is possible for the assembly manufacturer S to constantly identify a worker, a transport vehicle, or the like handling the electronic component accommodation reel 20, and to perform management such as accurately determining the current location of the electronic component accommodation reel 20.

In an electronic component management method according to the present example embodiment, the user-side steps further include the component supply device 57 serving as a mounter mounting each of the plurality of electronic components 10 accommodated in each of the electronic component accommodation reels 20 on an electronic circuit board, and the component supply device 57 stores a designated unique ID 57X serving as a designated unique number, and includes the RDID reader 58 serving as a second reader that reads the RFID tag 30, and the user-side steps further include comparing the unique ID 30X stored in the RFID tag 30 read by the RFID reader 58 with the designated unique ID 57X designated by the component supply device 57.

With such a configuration, it is confirmed whether or not the unique ID 30X of the electronic component accommodation reel 20 is the electronic component accommodation reel 20 in which the electronic components 10 to be mounted by the component supply device 57 are accommodated, and as a result, it is possible to prevent the electronic components 10 from being erroneously chosen.

In an electronic component management method according to the present example embodiment, the manufacturer-side steps further include storing, as the manufacturer-side information, the quantity information of the electronic components 10 accommodated in each of the electronic component accommodation reels 20 in the manufacturer-side information storage area 60G of the cloud 60, and the user-side steps further include determining the consumption amount of the electronic components 10 mounted on the electronic circuit board by the component supply device 57 based on the quantity information acquired based on the unique ID 30X, and preparing another received electronic component accommodation reel 20 based on the consumption amount.

With such a configuration, at the assembly manufacturer S, it is possible to quickly perform the replacement operation of replacing the electronic component accommodation reel 20 having completed the supply of the electronic components 10 to the component supply device 57 with a new electronic component accommodation reel 20 after the completion of the supply of the electronic components 10, and it is possible to continuously perform the mounting of the electronic components 10 even when the electronic component accommodation reel 20 is replaced. As a result, it is possible to improve productivity.

In an electronic component management method, the consumption amount of the electronic components 10 is associated with the unique ID 30X, and the unique ID 30X is stored in the user-side information storage area 60S of the cloud 60 and transmitted to the manufacturer.

With such a configuration, on the supplier G side, it is possible to accurately prepare the process of accommodating the electronic components 10 in the electronic component accommodation reel 20 based on the consumption amount of the electronic components 10 in the assembly manufacturer S.

In an electronic component management method, the manufacturer prepares the electronic component accommodation reel 20 based on the consumption amount of the electronic components 10 transmitted from the user.

With such a configuration, it is possible for the supplier G to efficiently prepare the electronic component accommodation reel 20 based on the consumption amount of the electronic components 10 on the assembly manufacturer S side.

In an electronic component management method according to the present example embodiment, at the supplier G, the unique ID 30Y on the supplier G side is used as a unique ID, while at the assembly manufacturer S, the unique ID 30Z on the assembly manufacturer S side is used as a unique ID, either one of the unique ID 30Y on the supplier G side or the unique ID 30Z on the assembly manufacturer S side is the same as the unique ID 30X, and either one of the unique ID 30Y on the supplier G side or the unique ID 30Z on the assembly manufacturer S side is associated with the unique ID 30X.

In an electronic component management method according to the present example embodiment, at the supplier G, the unique ID 30Y on the supplier G side is used as a unique ID, while at the assembly manufacturer S, the unique ID 30Z on the assembly manufacturer S side is used as a unique ID, and the unique ID 30Y on the supplier G and the unique ID 30Z on the assembly manufacturer S are associated with a common unique ID 30X.

With such a configuration, the supplier G and the assembly manufacturer S, or either one of the supplier G or the assembly manufacturer S can use its own unique ID (unique ID 30Y and unique ID 30Z), such that it is possible to operate the conventional unique ID distribution method, pattern, and the like without changing by each manufacturer.

Although example embodiments have been described above, the present invention is not limited to the above-described example embodiments, and modifications, improvements, and the like are included in the scope of the present invention.

For example, at the supplier G, the database server 44 may be omitted, and the unique ID 30X and the manufacturer side information may be directly stored in the manufacturer side information storage area 60G of the cloud 60. The same applies to the assembly manufacturer S, and the database server 54 may be omitted, and the unique ID 30X and the user side information may be directly stored in the user side information storage area 60S of the cloud 60.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component management method comprising:
manufacturer-side steps performed at a manufacturer-side facility where a manufacturer manufactures electronic components; and
user-side steps performed at a user-side facility where a user uses the electronic components manufactured in the manufacturer-side facility; wherein
the manufacturer-side steps include:
preparing an electronic component accommodation reel including a reel around which a tape accommodating a plurality of electronic components and an RFID tag storing a unique number is wound, the RFID tag being supplied to at least one of the tape or the reel;
storing manufacturer-side information in a manufacturer-side information storage area of an external storage device in association with the unique number; and
shipping the electronic component accommodation reel; and
the user-side steps include:
receiving and loading the electronic component accommodation reel shipped from the manufacturer-side facility;
reading the unique number stored in the RFID tag; and
acquiring, based on the unique number read, manufacturer-side information stored in the manufacturer-side information storage area of the external storage device.

2. The electronic component management method according to claim 1, wherein the manufacturer-side steps further include:
reading the manufacturer-side information based on the unique number;
creating a label based on the manufacturer-side information read; and
attaching the label to the electronic component accommodation reel.

3. The electronic component management method according to claim 1, wherein the manufacturer-side steps further include collectively reading the unique number from the RFID tag of each of a plurality of the electronic component accommodation reels upon shipping the plurality of electronic component accommodation reels each accommodating the plurality of electronic components.

4. The electronic component management method according to claim 1, wherein the user-side steps further include collectively reading the unique number from the RFID tag of each of a plurality of the electronic component accommodation reels upon receiving and loading the plurality of electronic component accommodation reels shipped.

5. The electronic component management method according to claim 1, wherein the user-side steps further include the user reading the RFID tag by a first reader installed at a predetermined location of the user-side facility to detect a location of the electronic component accommodation reel.

6. The electronic component management method according to claim 1, wherein the user-side steps further include a reel operator allocated at a predetermined location in the user-side facility reading the RFID tag to specify the reel operator.

7. The electronic component management method according to claim 1, wherein the user-side steps further include:
a mounter mounting each of the plurality of electronic components accommodated in each of the electronic component accommodation reels on an electronic circuit board;
the mounter storing a designated unique number and including a second reader that reads the RFID tag; and
the mounter comparing the unique number stored in the RFID tag read by the second reader with the designated unique number designated by the mounter.

8. The electronic component management method according to claim 7, wherein
the manufacturer-side steps further include storing, as the manufacturer-side information, quantity information of the electronic components accommodated in each of the electronic component accommodation reels in the manufacturer-side information storage area of the external storage device; and
the user-side steps further include determining a consumption amount of the electronic components mounted on the electronic circuit board by the mounter based on the quantity information acquired based on the unique number, and preparing another received electronic component accommodation reel based on the consumption amount.

9. The electronic component management method according to claim 8, wherein the consumption amount of the electronic components is associated with the unique number, and the unique number is stored in the user-side information storage area of the external storage device and transmitted to the manufacturer.

10. The electronic component management method according to claim 9, wherein the manufacturer prepares the electronic component accommodation reel based on the consumption amount of the electronic components transmitted from the user.

11. The electronic component management method according to claim 1, wherein
at the manufacturer-side facility, a manufacturer-side unique number is used as the unique number;
at the user-side facility, a user-side unique number is used as the unique number; and
either one of the manufacturer-side unique number or the user-side unique number is identical to the unique number, and either one of the manufacturer-side unique number or the user-side unique number is associated with the unique number.

12. The electronic component management method according to claim 1, wherein
at the manufacturer-side facility, a manufacturer-side unique number is used as the unique number;
at the user-side facility, a user-side unique number is used as the unique number; and
the manufacturer-side unique number and the user-side unique number are associated with the unique number.

13. An electronic component management method comprising:
manufacturer-side steps performed at a manufacturer-side facility where a manufacturer manufactures electronic components; and
user-side steps performed at a user-side facility where a user uses the electronic components manufactured at the manufacturer-side facility; wherein
the manufacturer-side steps include:
preparing an electronic component accommodation reel including a reel around which a tape accommodating a plurality of electronic components and an RFID tag supplied to at least one of the tape or the reel is wound;
preparing a unique number associated with manufacturer-side information;
storing the manufacturer-side information in a manufacturer-side information storage area of an external storage device in association with the unique number;
writing the unique number into the RFID tag; and
shipping the electronic component accommodation reel; and
the user-side steps include:
receiving and loading the electronic component accommodation reel shipped from the manufacturer-side facility;
reading the unique number stored in the RFID tag; and
acquiring, based on the unique number read, manufacturer-side information stored in the manufacturer-side information storage area of the external storage device.

14. The electronic component management method according to claim 13, wherein the manufacturer-side steps further include:
reading the manufacturer-side information based on the unique number;
creating a label based on the manufacturer-side information read; and
attaching the label to the electronic component accommodation reel.

15. The electronic component management method according to claim 13, wherein the manufacturer-side steps further include collectively reading the unique number from the RFID tag of each of a plurality of the electronic component accommodation reels upon shipping the plurality of electronic component accommodation reels each accommodating the plurality of electronic components.

16. The electronic component management method according to claim 13, wherein the user-side steps further include collectively reading the unique number from the RFID tag of each of a plurality of the electronic component accommodation reels upon receiving and loading the plurality of electronic component accommodation reels shipped.

17. The electronic component management method according to claim 13, wherein the user-side steps further include the user reading the RFID tag by a first reader installed at a predetermined location of the user-side facility to detect a location of the electronic component accommodation reel.

18. The electronic component management method according to claim 13, wherein the user-side steps further include a reel operator allocated at a predetermined location in the user-side facility reading the RFID tag to specify the reel operator.

19. The electronic component management method according to claim 13, wherein the user-side steps further include:
a mounter mounting each of the plurality of electronic components accommodated in each of the electronic component accommodation reels on an electronic circuit board;
the mounter storing a designated unique number and including a second reader that reads the RFID tag; and
the mounter comparing the unique number stored in the RFID tag read by the second reader with the designated unique number designated by the mounter.

20. The electronic component management method according to claim 19, wherein
the manufacturer-side steps further include storing, as the manufacturer-side information, quantity information of the electronic components accommodated in each of the electronic component accommodation reels in the manufacturer-side information storage area of the external storage device; and
the user-side steps further include determining a consumption amount of the electronic components mounted on the electronic circuit board by the mounter based on the quantity information acquired based on the unique number, and preparing another received electronic component accommodation reel based on the consumption amount.

21. The electronic component management method according to claim 20, wherein the consumption amount of the electronic components is associated with the unique number, and the unique number is stored in the user-side information storage area of the external storage device and transmitted to the manufacturer.

22. The electronic component management method according to claim 21, wherein the manufacturer prepares the electronic component accommodation reel based on the consumption amount of the electronic components transmitted from the user.
